(19) United States
(12) Patent Application Publication
(10) Pub. No.: US 2006/0141702 A1
(43) Pub. Date: Jun. 29, 2006

(54) Method for depositing titanium oxide layer and method for fabricating capacitor by using the same

(76) Inventors: Hyun-Kyung Woo, Kyoungki-do (KR); Seung-Jin Yeom, Kyoungki-do (KR); Deok-Sin Kil, Kyoungki-do (KR); Kwon Hong, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/150,421

(22) Filed: Jun. 9, 2005

(30) Foreign Application Priority Data
Dec. 28, 2004 (KR) 2004-0113715

(51) Int. Cl. H01L 21/8242; H01L 21/20; H01L 21/44

(52) U.S. Cl. 438/250; 438/253; 438/393; 438/396; 438/785; 438/680

(57) ABSTRACT

Disclosed are a method for depositing a titanium oxide (TiO₂) layer and a method for fabricating a capacitor by using the same. The method for forming the TiO₂ layer includes the steps of: a) adsorbing titanium hydride (TiH₂) on a wafer loaded into a chamber by supplying TiH₂ to the chamber; b) purging out the non-adsorbed TiH₂; c) forming an TiO₂ layer on the wafer by inducing a reaction between the TiH₂ and the oxygen source with supplying an oxygen source as a reaction gas to the chamber; and d) purging out the non-reacted oxygen source and a by-product. The method for fabricating the capacitor includes the steps of: forming a lower electrode on a wafer; depositing a titanium oxide (TiO₂) layer on the lower electrode by using titanium hydride (TiH₂) as a precursor; and forming an upper electrode on the TiO₂ layer.

### FIELD OF THE INVENTION

The present invention relates to a method for fabricating a semiconductor device; and more particularly, to a method for fabricating a capacitor.

### DESCRIPTION OF RELATED ARTS

As a minimum line width has decreased and a scale of integration of a semiconductor device has increased, an area where a capacitor is formed has decreased. Even though the area where the capacitor is formed has decreased, a capacitor within a cell is compelled to secure a minimum dielectric amount per cell. In order to form the capacitor having a high dielectric capacity in the decreased area, it is necessary to reduce a thickness of a dielectric layer or apply a substance with a high dielectric constant.

Presently, a method for securing the dielectric capacity by reducing the thickness of the dielectric layer with use of a high dielectric layer such as hafnium oxide (HfO₂) has been eventually reached a limitation for a dynamic random access memory (DRAM) with a size equal to or less than 60 nm.

Accordingly, an effort to form the capacitor by applying a substance having a dielectric constant higher than HfO₂ has been developed.

FIG. 1 is a cross-sectional view illustrating a structure of a conventional capacitor.

As shown in FIG. 1, the conventional capacitor is provided with a lower electrode 11, a titanium oxide (TiO₂) layer 12 on the lower electrode 11 and an upper electrode 13 on the TiO₂ layer 12.

The TiO₂ layer 12 used for a dielectric layer of the capacitor has a very high dielectric constant which is 100. However, the capacitor using TiO₂ as the dielectric material has a very high concentration that induces various defects at an interface between the TiO₂ layer and the lower electrode and thus, a leakage current property becomes degraded. Accordingly, the TiO₂ layer cannot be used for the capacitor.

The degraded leakage current property is caused by impurities such as carbon and hydrogen. Herein, these impurities are produced due to an incomplete decomposition of titanium (Ti) ligands among Ti organic precursors, e.g., Ti(OC₃H₇)₄ and Ti(O₃H₇)₂(C₁₁H₁₉O₂)₂, used as a precursor when a chemical vapor deposition (CVD) method or an atomic layer deposition (ALD) method is employed during forming the TiO₂ layer.

The impurities remaining within the TiO₂ layer deteriorates a good material property that the TiO₂ layer has and also functions as a defect source within the TiO₂ layer, thereby degrading the leakage current property.

### SUMMARY OF THE INVENTION

It is, therefore, an object of the present invention to provide a method for depositing a titanium oxide (TiO₂) layer by using a precursor providing an advantage in productivity as impurities such as carbon and hydrogen do not remain within the TiO₂ layer and a method for fabricating a capacitor by using the same.

In accordance with one aspect of the present invention, there is provided a method for forming a titanium oxide (TiO₂) layer, including the steps of: a) adsorbing titanium hydride (TiH₂) on a wafer loaded into a chamber by supplying TiH₂ to the chamber; b) purging out the non-adsorbed TiH₂; c) forming an TiO₂ layer on the wafer by inducing a reaction between the TiH₂ and the oxygen source with supplying an oxygen source as a reaction gas to the chamber; and d) purging out the non-reacted oxygen source and a by-product.

In accordance with another aspect of the present invention, there is provided a method for fabricating a capacitor, including the steps of: forming a lower electrode on a wafer; depositing a titanium oxide (TiO₂) layer on the lower electrode by using titanium hydride (TiH₂) as a precursor; and forming an upper electrode on the TiO₂ layer.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a cross-sectional view illustrating a structure of a conventional capacitor;

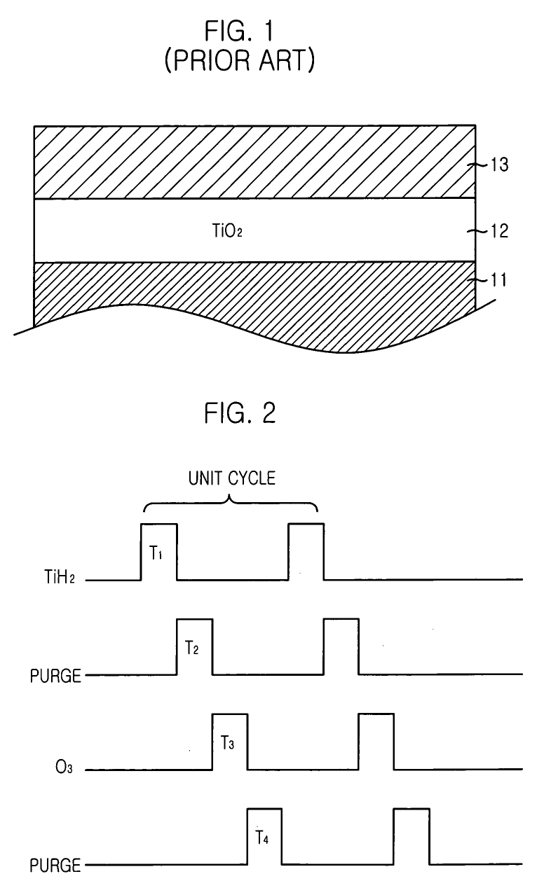

FIG. 2 is a diagram illustrating an atomic layer deposition mechanism of a titanium oxide (TiO₂) layer in accordance with the present invention; and

FIGS. 3A to 3D are cross-sectional views illustrating a method for fabricating a capacitor using the TiO₂ layer shown in FIG. 2 as a dielectric layer in accordance with the present invention.

### DETAILED DESCRIPTION OF THE INVENTION

Hereinafter, detailed descriptions on a preferred embodiment of the present invention will be provided with reference to the accompanying drawings.

The preferred embodiment of the present invention described hereinafter provides a method for fabricating a titanium oxide (TiO₂) layer for a capacitor of a dynamic random access semiconductor (DRAM) by using titanium hydride (TiH₂). TiH₂ used in this preferred embodiment of the present invention does not contain carbon (C) and oxygen (O) but contains a relatively small amount of hydrogen (H). Accordingly, TiH₂ is different from conventionally used metal organic sources such as Ti(OC₃H₇)₄ and Ti(O₃H₇)₂(C₁₁H₁₉O₂)₂ for depositing the TiO₂ layer as a dielectric layer of the capacitor.

If TiH₂ is used as a precursor, the TiO₂ layer is deposited through a decomposition step shown below.
TiH₂+O₃→TiO₂+H₂O eq. 1

In the above equation 1, TiH₂ and ozone (O₃) act as a titanium (Ti) precursor and a reaction gas, respectively. Also, deionized water (H₂O) which is a by-product of the reaction volatilizes.

A method for depositing the TiO₂ layer by using the TiH₂ employs an atomic layer deposition (ALD) method.

For the ALD method, a wafer is loaded into a chamber. Then, a precursor is provided to the chamber, so that the precursor is chemically adsorbed onto the wafer. Afterwards, a purge gas such as an inert gas is provided, thereby discharging an extra precursor. Thereafter, the reaction gas is continuously provided and then, an atomic thin layer is deposited by inducing a surface reaction between the precursor chemically absorbed and the reaction gas. Then, the purge gas such as the inert gas is provided again, thereby discharging the extra reaction gas and extra reaction by-products. The ALD method overcomes a limitation in a step coverage by a chemical vapor deposition (CVD) method at a region where an aspect ratio is high. If the ALD method is used, a single layer is deposited at a time. Accordingly, the ALD method provides a good step coverage and makes it possible to deposit the single layer in a low temperature. Thus, the ALD method provides an advantage in reducing a thermal budget with respect to a bottom structure.

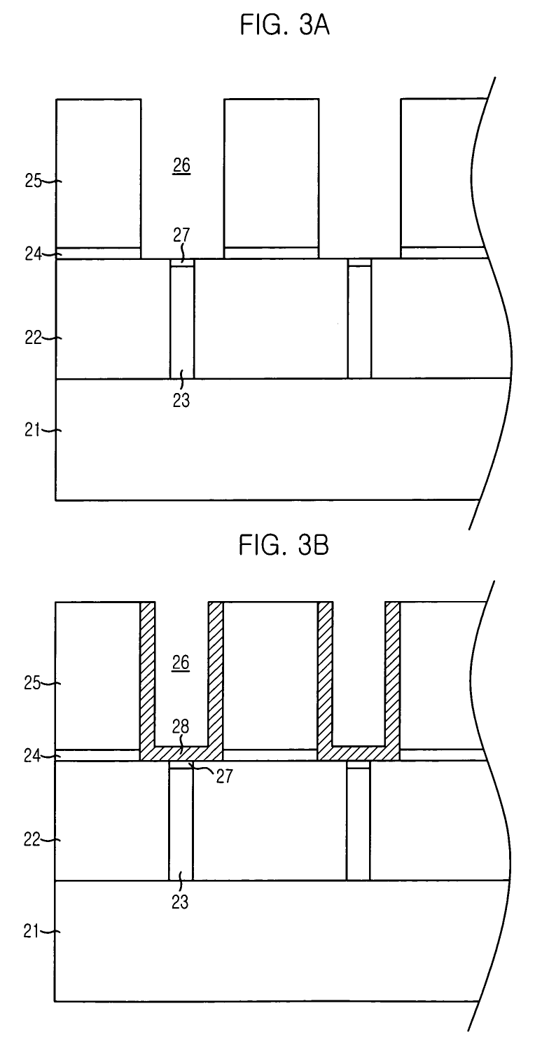

FIG. 2 is a diagram illustrating an atomic layer deposition mechanism of a TiO₂ layer in accordance with the present invention.

Referring to FIG. 2, a wafer provided with a bottom structure is loaded into an ALD chamber. Afterwards, TiH₂ is flowed into the ALD chamber as a precursor of Ti for a period (T₁) ranging from approximately 0 second to approximately 10 seconds. At this time, when TiH₂ is carried to an inner side of the ALD chamber, an argon (Ar) gas or a nitrogen (N₂) gas is used as a carrier gas. When the TiH₂ is flowed, the ALD chamber is maintained with a pressure ranging from approximately 0.1 torr to approximately 20 torr, and the wafer is heated at a low temperature ranging from approximately 200° C. to approximately 350° C. That is, the TiO₂ layer is heated at a low temperature ranging from approximately 200° C. to approximately 350° C.

If the TiH₂ is supplied to the ALD chamber in the above descried conditions, the TiH₂ is chemically adsorbed on a surface of a bottom structure.

Continuously, a purge gas such as Ar or N₂ is provided to the ALD chamber during a period (T₂) ranging from approximately 0 second to approximately 10 seconds in order to remove the non-reacted TiH₂ and a reaction by-product.

Next, O₃ that is an oxygen source is flowed into the ALD chamber during a period (T₃) ranging from approximately 0 second to approximately 10 seconds. Accordingly, the TiH₂ and the O₃ that have been already chemically adsorbed on the surface of the bottom structure are reacted with each other as the above chemical equation 1 shows and as a result of the reaction between the TiH₂ and the O₃, the aforementioned TiO₂ layer is formed in an atomic layer unit. Herein, O₂ plasma or H₂O also can be used as the oxygen source in addition to the O₃.

Again, the pure gas such as Ar or N₂ is flowed into the ALD chamber during a period (T₄), thereby removing the O₃ that has not yet reacted and a by-product, e.g., H₂O. At this time, the purging period (T₄) ranges from approximately 0 second to approximately 10 seconds.

These steps of supplying the TiH₂ as the Ti precursor, purging out the non-adsorbed TiH₂, supplying the O₃ and purging out the non-reacted TiH₂ and O₃ and the by-product comprises a unit cycle for the ALD method and this unit cycle is repeated many times, thereby depositing the TiO₂ layer with an intended thickness.

If the TiO₂ layer is deposited by using TiH₂ as the Ti precursor, impurities such as carbon and hydrogen worsening a leakage current problem of a capacitor do not remain inside of the TiO₂ layer.

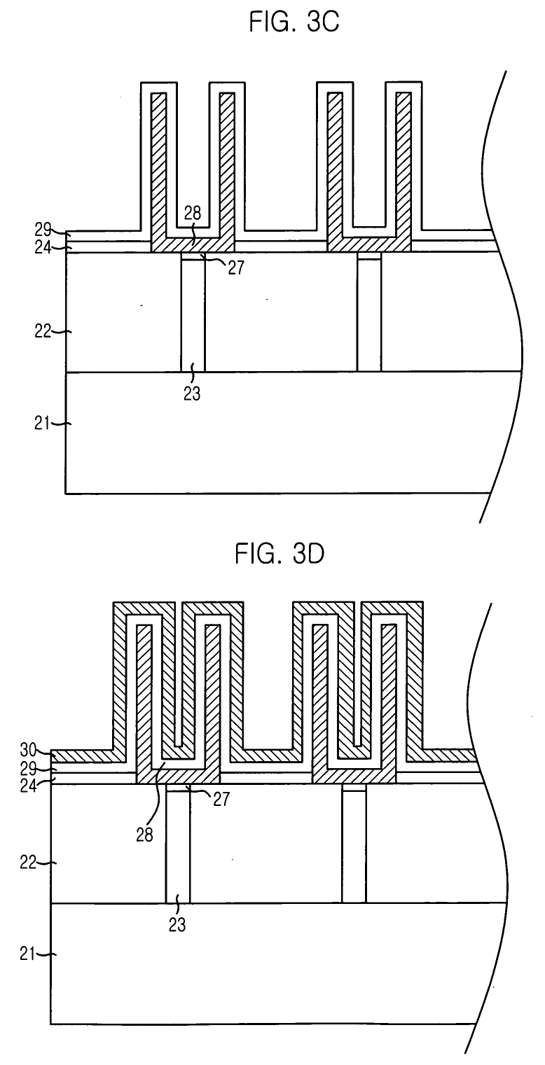

FIGS. 3A to 3D are cross-sectional views illustrating a method for fabricating a capacitor using the TiO₂ layer shown in FIG. 2 as a dielectric layer in accordance with the present invention.

Referring to FIG. 3A, an inter-layer insulation layer 22 is formed on a substrate 21 provided with various device elements. Herein, before forming the inter-layer insulation layer 22, word lines, transistors and bit lines are formed so that the inter-layer insulation layer 22 can be a multi-layer structure. The substrate 21 can be a typical silicon substrate or a gallium arsenic (GaAs) substrate.

Next, although not illustrated, the inter-layer insulation layer 22 is etched by using a storage node contact mask to form storage node contact holes exposing portions of the substrate 21, i.e., source/drain regions of the transistors. Then, a plurality of storage node contact plugs 23 are formed by burying polysilicon in the storage node contact holes. In more detail of the formation of the storage node contact plugs 23, a polysilicon layer is deposited until filling the storage node contact holes and then, a surface of the polysilicon layer is planarized by employing a chemical mechanical polishing (CMP) process or an etch-back process.

Continuously, an etch barrier layer 24 and a storage node oxide layer 25 are deposited on the inter-layer insulation layer 22 in which the plurality of storage node contact plugs 23 are buried. At this time, the etch barrier layer 24 serves a role in preventing a loss of the inter-layer insulation layer 22 during an etching process to be performed later to the storage node oxide layer 25. The etch barrier layer 24 includes a specific etch selectivity with respect to the storage node oxide layer 25. For instance, the etch barrier layer 24 includes a silicon nitride (Si₃N₄) layer and the storage node oxide layer 25 is a silicon oxide (SiO₂)-based layer formed by using a material selected from a group consisting of a borophosphosilicateglass (BPSG) layer, a high density plasma oxide (HDP) layer, a tetraethylorthosilicate (TEOS) layer and a undoped silicate glass (USG) layer. Furthermore, the storage node oxide layer 25 is formed in a thickness capable of securing a desired capacitance, i.e., the thickness ranging from approximately 20,000 Å to approximately 30,000 Å.

Subsequently, the etch barrier layer 24 and the storage node oxide layer 25 are sequentially etched, thereby forming a plurality of storage node holes 26 opening upper portions of the plurality of storage node contact plugs 23, respectively. At this time, the storage node oxide layer 25 is etched by using the etch barrier layer 24 as an etch barrier and then, the etch barrier layer 24 is selectively etched, thereby forming the plurality of storage node holes 26.

Next, a titanium silicide (TiSi₂) layer 27 serving a role as a barrier metal is formed on a surface of the individual storage node contact plugs 23 exposed at bottoms of the respective storage node holes 26.

At this time, for the step of forming the TiSi₂ layer 27, Ti is first deposited on the storage node oxide layer 25 and the plurality of storage node holes 26. Afterwards, a rapid annealing process is performed, thereby forming the TiSi₂ layer 27. Then, the Ti that has not yet reacted is removed. Especially, the above Ti is deposited by using one of a CVD method, a physical vapor deposition (PVD) method and an ALD method. The rapid annealing process is performed in a N₂ atmosphere or a vacuum atmosphere with a temperature ranging from approximately 600° C. to approximately 850° C. for approximately 20 seconds to approximately 30 seconds.

The TiSi₂ layer 27 provides an ohmic contact between each two of the storage node contact plugs 23 and subsequent lower electrodes. The TiSi₂ layer 27 especially improves a contact resistance property.

Referring to FIG. 3B, a conductive layer for use in a lower electrode is deposited on an entire surface of the above resulting substrate structure. Afterwards, a lower electrode isolation process is employed, thereby forming a plurality of cylinder type lower electrodes 28 inside of the plurality of storage node holes 26.

For the step of forming the plurality of lower electrodes 28, a conductive layer is based on a material selected from a group consisting of a doped silicon having conductivity by being doped with As or phosphorous (P), Ti, titanium nitride (TiN), hafnium nitride (HfN), vanadium nitride (VN), tungsten (W), tungsten nitride (WN), platinum (Pt), ruthenium (Ru), ruthenium oxide (RuO₂), iridium (Ir), iridium oxide (IrO₂), rhodium (Rh) and palladium (Pd). Also, the conductive layer is deposited in a thickness ranging from approximately 20 Å to approximately 300 Å through a method selected among a PVD method, a CVD method, an ALD method and an electroplating method. Next, the lower electrode isolation process makes the plurality of lower electrodes 28 formed only inside of the plurality of storage node holes 26 by removing the conductive layer formed on an upper portion of the storage node oxide layer 25 through a CMP process or an etch-back process. When the conductive layer is removed, there is a possibility that impurities such as etch remnants or abrasives are stuck inside of the cylinder type lower electrodes 28. Accordingly, it is preferred that a photoresist having a good step coverage is filled into the plurality of storage node holes 26 and then, a polishing process or an etch-back process is employed until a surface of the storage node oxide layer 25 is exposed. Afterwards, the photoresist remaining inside of the plurality of storage node holes 26 is removed by ashing.

Referring to FIG. 3C, the storage node oxide layer 25 is removed through a wet type full dip-out process. At this time, a chemical capable of minimizing a loss of a metal used for the lower electrodes 28 and selectively removing only the storage node oxide layer 25 is used for the wet type full dip-out process. For instance, a chemical containing a buffered oxide etchant (BOE) solution or hydrogen fluoride (HF) is an example of such chemical used for the wet type full dip-out process. At this time, a chemical containing ammonium fluoride (NH₄F) or a surfactant can also be mixed with the above chemical to control an etching ratio. Herein, polyethylene glycol is used as the surfactant.

After the wet type full dip-out process, inner walls and outer walls of the plurality of lower electrodes 28 are exposed.

Referring to FIG. 3C, a TiO₂ layer 29 is deposited on the plurality of lower electrodes 28 in a thickness ranging from approximately 30 Å to approximately 150 Å through the ALD method described in FIG. 2.

Herein, the sequential steps of depositing the TiO₂ layer 29 in a single atomic layer basis are performed as shown in FIG. 2. That is, these steps of supplying the TiH₂ as the Ti precursor, purging out the non-adsorbed TiH₂, supplying the O₃ and purging out the non-adsorbed TiH₂, O₃ and the by-product comprises a unit cycle for the ALD method and this unit cycle is performed repeatedly, thereby depositing the TiO₂ layer 29 with an intended thickness ranging from approximately 30 Å to approximately 150 Å. Also, during depositing the atomic layer of the TiO₂ layer 29, a deposition temperature ranges from approximately 200° C. to approximately 350° C.

After the TiO₂ layer 29 is deposited, a post-treatment process is employed to improve a dielectric property of the TiO₂ layer 29. The post-treatment process is performed in an atmosphere of O₂, O₃ or O₂ plasma and a temperature ranging from approximately 200° C. to approximately 500° C.

Referring to FIG. 3D, a conductive layer for use in an upper electrode is deposited on the TiO₂ layer 29 and then, patterned to form an upper electrode 30.

At this time, the conductive layer used for the upper electrode 30 is made of a material selected from a group consisting of a doped silicon having conductivity by being doped with As or P, Ti, TiN, HfN, VN, W, WN, Pt, Ru, RuO₂, Ir, IrO₂, Rh and Pd. The conductive layer is deposited in a thickness ranging from approximately 20 Å to approximately 300 Å through one of a PVD method, a CVD method, an ALD method and an electroplating method.

The TiO₂ layer in accordance with the present invention can be used as a dielectric layer for a concave type capacitor and a stack type capacitor in addition to the cylinder type capacitor.

The TiO₂ layer 29 is formed as the dielectric layer by using TiH₂ that does not contain carbon and oxygen but contains a small amount of hydrogen and as a result of this specific usage, it is possible to prevent a deterioration of the leakage current property caused by an impurity contamination.

Also, this advantage further provides an effect of improving reliability of the capacitor.

The present application contains subject matter related to the Korean patent application No. KR 2004-0113715, filed in the Korean Patent Office on Dec. 28, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a titanium oxide (TiO₂) layer, comprising the steps of:
a) adsorbing titanium hydride (TiH₂) on a wafer loaded into a chamber by supplying TiH₂ to the chamber;
b) purging out the non-adsorbed TiH₂;
c) forming an TiO₂ layer on the wafer by inducing a reaction between the TiH₂ and the oxygen source with supplying an oxygen source as a reaction gas to the chamber; and
d) purging out the non-reacted oxygen source and a by-product.

2. The method of claim 1, wherein the TiO₂ layer is deposited at a temperature ranging from approximately 200° C. to approximately 350° C.

3. The method of claim 1, wherein the TiO₂ layer is deposited in a thickness ranging from approximately 30 Å to approximately 150 Å.

4. The method of claim 1, wherein the oxygen source is one of ozone (O₃), oxygen (O₂) plasma and deionized water (H₂O)

5. The method of claim 1, wherein the steps from a) to d) are repeated to deposit the TiO₂ layer.

6. A method for fabricating a capacitor, comprising the steps of:
forming a lower electrode on a wafer;
depositing a titanium oxide (TiO₂) layer on the lower electrode by using titanium hydride (TiH₂) as a precursor; and
forming an upper electrode on the TiO₂ layer.

7. The method of claim 6, wherein the step of depositing the TiO₂ layer is performed through employing an atomic layer deposition (ALD) method.

8. The method of claim 7, further including the steps of:
loading the wafer provided with the lower electrode into an ALD chamber;
supplying TiH₂ to the ALD chamber, thereby adsorbing the TiH₂ on a surface of the lower electrode;
purging out the non-adsorbed TiH₂;
forming the TiO₂ layer on the lower electrode as a thin atomic layer by inducing a reaction between the TiH₂ and the oxygen source with supplying an oxygen source as a reaction gas to the ALD chamber; and
purging out the non-reacted oxygen source and a by-product.

9. The method of claim 8, wherein a deposition temperature of the TiO₂ layer ranges from approximately 200° C. to approximately 350° C.

10. The method of claim 8, wherein the oxygen source is one of O₃, O₂ plasmas and H₂O.

11. The method of claim 6, wherein the TiO₂ layer is deposited in a thickness ranging from approximately 30 Å to approximately 150 Å.

12. The method of claim 6, wherein after the step of depositing the TiO₂ layer, a post-treatment process is performed to improve a dielectric property of the TiO₂ layer.

13. The method of claim 12, wherein the post-treatment process is performed in one selected atmosphere from a group consisting of O₂, O₃ and O₂ plasma with a temperature ranging from approximately 200° C. to approximately 500° C.

14. The method of claim 6, wherein the lower electrode and the upper electrode induce a material selected from a group consisting of a doped silicon having conductivity by being doped with one of arsenic (As) and phosphorous (P), Ti, titanium nitride (TiN), hafnium nitride (HfN), vanadium nitride (VN), tungsten (W), tungsten nitride (WN), platinum (Pt), ruthenium (Ru), ruthenium oxide (RuO₂), iridium (Ir), iridium oxide (IrO₂), rhodium (Rh) and palladium (Pd).

15. The method of claim 8, wherein the ALD chamber is maintained at a pressure ranging from approximately 0.1 torr to approximately 20 torr.

16. The method of claim 1, wherein at the step of purging out the non-adsorbed TiH₂, a purging gas is flowed in to an ALD chamber for a period ranging from approximately 0 second to approximately 10 seconds.

17. The method of claim 1, wherein at the step of forming the TiO₂ layer, the oxygen source is flowed into an ALD chamber for a period ranging from approximately 0 second to approximately 10 seconds.

18. The method of claim 1, wherein at the step of purging out the non-reacted oxygen and the by-product, a purging gas is flowed into an ALD chamber for a period ranging from approximately 0 second to approximately 10 seconds.
